(19) United States
(12) Patent Application Publication
(10) Pub. No.: US 2006/0205223 A1
(43) Pub. Date: Sep. 14, 2006

(54) Line edge roughness reduction compatible with trimming

(76) Inventor: Michael C. Smayling, Fremont, CA (US)

Correspondence Address: PATTERSON & SHERIDAN, LLP, 3040 POST OAK BOULEVARD, SUITE 1500, HOUSTON, TX, 77056, US

(21) Appl. No.: 11/315,941

(22) Filed: Dec. 22, 2005

Related U.S. Application Data
(60) Provisional application No. 60/640,504, filed on Dec. 30, 2004.

(51) Int. Cl. H01L 21/302; H01L 21/461

(52) U.S. Cl. 438/725

(57) ABSTRACT

A method and apparatus for reducing line edge roughness, comprising patterning a photoresist to define lines for etching an underlying layer, depositing a post development material between the lines, curing and removing the post development material to reduce line edge roughness, trimming the lines in the underlying layer, and then etching the underlying layer.

### CROSS-REFERENCE TO RELATED APPLICATIONS

This application claims benefit of U.S. Provisional Patent Application Ser. No. 60/640,504, filed Dec. 30, 2004, which is herein incorporated by reference.

### BACKGROUND OF THE INVENTION

1. Field of the Invention

The present invention generally relates to a method for fabricating devices on semiconductor substrates. More specifically, the present invention relates to a method for fabricating a gate structure of a field effect transistor.

2. Description of the Related Art

Ultra-large-scale integrated (ULSI) circuits typically include more than one million transistors that are formed on a semiconductor substrate and cooperate to perform various functions within an electronic device. Such transistors may include complementary metal-oxide-semiconductor (CMOS) field effect transistors.

A CMOS transistor includes a gate structure that is disposed between a source region and a drain region defined in the semiconductor substrate. The gate structure generally comprises a gate electrode formed on a gate dielectric material. The gate electrode controls a flow of charge carriers, beneath the gate dielectric, in a channel region that is formed between the drain and source regions, so as to turn the transistor on or off. The channel and drain and source regions are collectively referred to in the art as a “transistor junction”. There is a constant trend to reduce the dimensions of the transistor junction and, as such, decrease the gate electrode width in order to facilitate an increase in the operational speed of such transistors.

In a CMOS transistor fabrication process, a lithographically patterned mask is used during etch and deposition processes to form the gate electrode. However, as the dimensions of the transistor junction decrease (e.g., dimensions less than about 100 nm), it is difficult to accurately define the gate electrode width using conventional lithographic techniques.

Therefore, there is a need in the art for a method of fabricating a gate structure of a field effect transistor having reduced dimensions.

### SUMMARY OF THE INVENTION

The present invention generally provides a method and an apparatus for reducing line edge roughness comprising patterning a photoresist to define lines for etching an underlying layer, depositing a post development material between the lines, curing and removing the post development material to reduce line edge roughness, trimming the lines in the underlying layer, and then etching the underlying layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a flow diagram of a method of fabricating a gate structure of a field effect transistor in accordance with the present invention.

FIGS. 2A-2J depict schematic, cross-sectional and top plan views of a substrate having a gate structure being formed in accordance with the method of FIG. 1.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the present invention provide a method for fabricating features on a substrate having reduced dimensions. The features are formed by defining a first mask on regions of the substrate. The mask is deposited on the substrate and then defined using lithographic techniques including use of a shrink resist and trimming to reduce line edge roughness. The features are formed on the substrate by etching portions of the substrate exposed by the mask.

The present invention is illustratively described with reference to a method for fabricating a gate structure of a field effect transistor on a substrate. The gate structure comprises a gate electrode formed on a gate dielectric layer. The gate structure is fabricated by depositing a gate electrode layer on a gate dielectric layer over a plurality of regions wherein transistor junctions are to be defined on the substrate. A underlying layer, such as a mask, is formed as described below on regions of the gate electrode layer between adjacent regions where the transistor junctions are to be formed. The gate structure is completed by etching the gate electrode layer to the gate dielectric layer using the underlying layer.

The thickness of the mask conformably formed is used to determine the width of the gate electrodes of the transistors. The mask width depends on a deposition process, rather than on a lithography process, advantageously providing gate widths less than 30 nm.

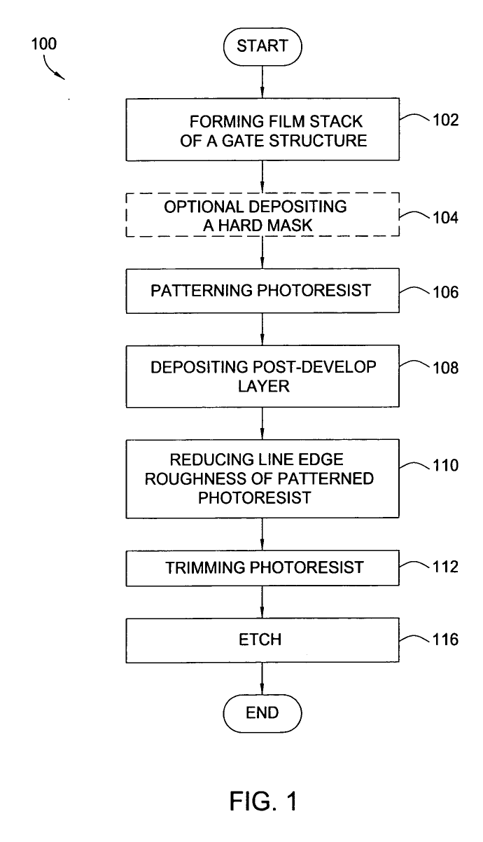

FIG. 1 depicts a flow diagram of a process sequence 100 for fabricating a gate electrode in accordance with the present invention. The sequence 100 comprises process steps that are performed upon a gate electrode film-stack during fabrication of a field effect transistor (e.g., CMOS transistor).

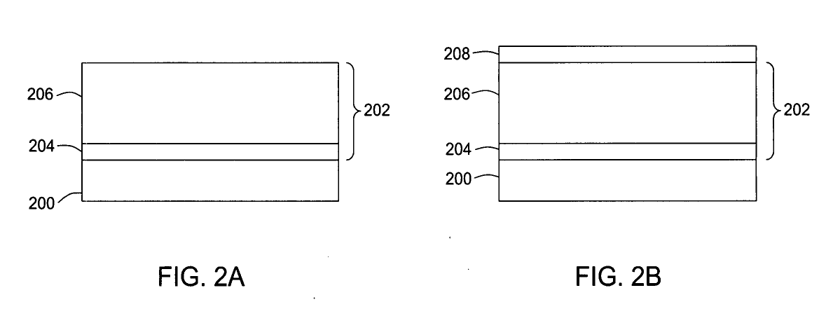

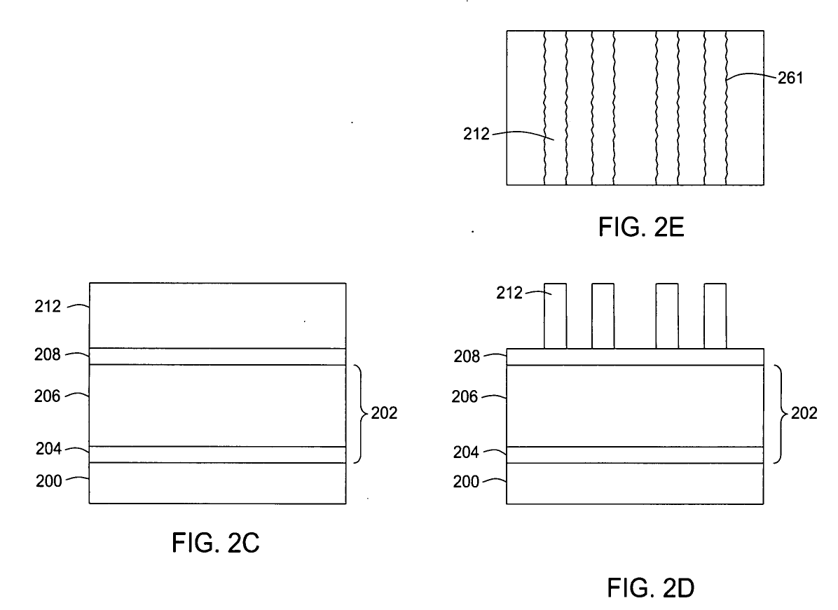

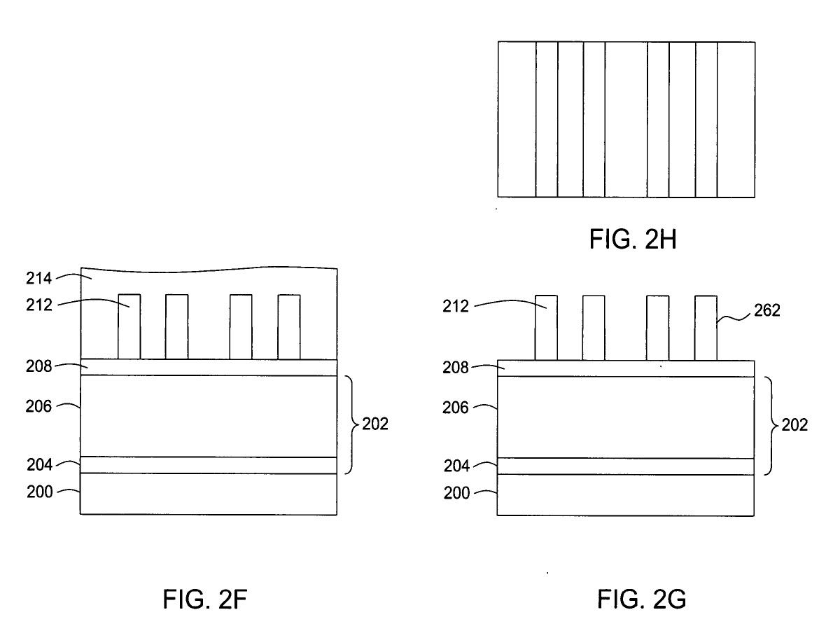

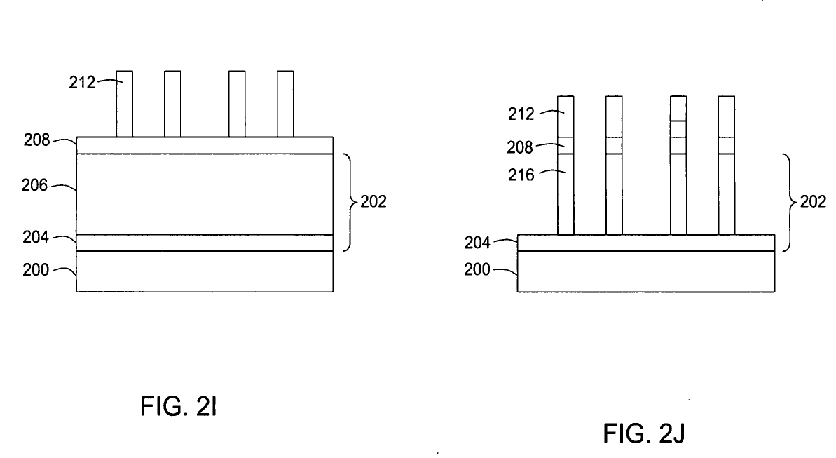

FIGS. 2A-2J depict a sequence of schematic cross-sectional views (FIGS. 2A-D, 2F-G, 2I-J) and top plan views (FIGS. 2E and 2H) of a substrate showing a gate electrode being formed thereon using process sequence 100 of FIG. 1. To best understand the invention, the reader should simultaneously refer to FIGS. 1 and 2A-2J. The views in FIGS. 2A-2J relate to individual processing steps that are used to form the gate electrode. Sub-processes and lithographic routines (e.g., exposure and development of photoresist, wafer cleaning procedures, and the like) are not shown in FIG. 1 and FIGS. 2A-2J. The images in FIGS. 2A-2J are not depicted to scale and are simplified for illustrative purposes.

Process sequence 100 begins at film stack formation step 102 (FIG. 1) by forming a gate electrode stack 202 on a wafer 200 (FIG. 2A).

The gate electrode stack 202 comprises a gate electrode layer 206 formed on a dielectric layer 204. The gate electrode layer 206 is formed, for example, of doped polysilicon (Si) to a thickness of up to about 2000 Angstroms. The dielectric layer 204 is formed, for example, of silicon dioxide (SiO₂) to a thickness of about 20 to 60 Angstroms. The gate dielectric layer 204 may optionally consist of one or more layers of material such as, for example, silicon dioxide (SiO₂), hafnium silicon dioxide (HfSiO₂) and aluminum oxide (Al₂O₃) to a thickness equivalent to that of the single silicon dioxide (SiO₂) layer. It should be understood, however, that the gate electrode stack 202 may comprise layers formed from other materials or layers having different thicknesses.

The layers that comprise the gate electrode stack 202 may be deposited using a vacuum deposition technique such as atomic layer deposition (ALD), physical vapor deposition (PVD), chemical vapor deposition (CVD), evaporation, and the like. Fabrication of the CMOS field effect transistors may be performed using the respective processing modules of CENTURA® platforms, ENDURA® platforms, and other semiconductor wafer processing systems available from Applied Materials, Inc. of Santa Clara, Calif.

At optional step 104 (FIG. 1), the process sequence continues by depositing an optional hardmask 208 (FIG. 2B). The optional hardmask 208 is preferably a dielectric anti-reflective coating (DARC) that is sequentially formed on the gate electrode layer 206 (FIG. 2B). In one illustrative embodiment, the optional hardmask 208 may comprise silicon oxynitride (SiON), silicon dioxide (SiO₂), or other material to a thickness of about 100 to about 600 Angstroms. The optional hardmask 208 functions to minimize the reflection of light during patterning steps. As feature sizes are reduced, inaccuracies in etch mask pattern transfer processes can arise from optical limitations that are inherent to the lithographic process, such as light reflection. DARC deposition techniques are described in commonly assigned U.S. Pat. No. 6,573,030, filed Jun. 8, 2000 and U.S. patent application Ser. No. 09/905,172 filed Jul. 13, 2001, which are herein incorporated by reference.

Step 106 comprises preparing a photoresist (FIG. 1), and includes depositing a photoresist (FIG. 2C) and developing the photoresist (FIG. 2D). The photoresist layer 212 may be formed using any conventional deposition technique.

Step 106 is illustrated by FIGS. 2D and 2E. The photoresist is patterned by forming a patterned mask (e.g., photoresist mask) on the material layer beneath such a mask (i.e., underlying layer) and then etching the material layer using the patterned mask as an etch mask.

The patterned photoresists 212 are conventionally fabricated using a lithographic process when a pattern of the feature to be formed is optically transferred into the layer of photoresist. For example, the photoresist is illuminated by UV light, a post-exposure bake at about 130° C. is performed and unexposed portions of the photoresist are removed by a developer, while the remaining photoresist retains the pattern.

Typically, the patterned photoresist comprises elements having the same critical dimensions as the feature to be formed. However, optical limitations of the lithographic process may not allow transferring a dimensionally accurate image of a feature into the photoresist layer when a CD of the element is smaller than optical resolution of the lithographic process.

Step 106 results in rough lines as shown in FIG. 2E, a top view of the photoresist 212 as shown in FIG. 2D. The sidewalls 261 of the photoresist 212 have jagged edges as shown in FIG. 2E.

Next, a post develop layer is deposited during step 108 (FIG. 1). A shrink resist layer 214 is deposited to engulf the patterened photoresist 212, for example, by spin coating. The thickness of the shrink resist layer is selected to be thick enough to engulf the photoresist mask 212, but thin enough to cure properly. In some embodiments, 100 nm may be applied. A shrink resist layer may include a resin such as poly(methyladamantyltrifluoromethacrylate(MAFMA)-norbornenehexafluoroisopropanol(NBHFA)) and a photo acid generator such as triphenylsulfonium nonaflate. The components may be formulated and purchased from Fujifilm Arch Co., Ltd. Alternatively, Tokyo Ohka Kogyo, Lt. and Hitachi, Ltd. have developed SAFIER™ which also contains an acid and water soluble resin and additives. Also, RELACS™ was developed by and is available for purchase from Clariant and Mitsubishi Electronics and is an aqueous polymer which has hydroxyl groups and a cross linking component.

Reducing line edge roughness of patterned photoresist step 110 is illustrated by FIGS. 2G and 2H. The shrink resist layer is cured by preheating at 100° C. for about 20 to about 90 seconds, and then the bake temperature is raised to about 120 to about 150° C., preferably about 130 to about 140° C. The optional final shrinkage process temperature was adjusted between 172 and 180° C. for 60 seconds. Generally, curing the shrink resist layer may be performed over 100-180° C. The sidewalls 262 of the photoresist mask 212 are smoothed and straightened as the shrink resist layer is cured. Next, the substrates may be rinsed with de-ionized water for about 20 to about 180 seconds, preferably 60 seconds to remove the residual shrink resist. The resulting decrease in the jagged surfaces is illustrated by FIG. 2H. The resulting line width can be larger than it was prior to the steps 108 and 110.

The trimming photoresist step 112 is illustrated by FIG. 2I. In one illustrative embodiment, the width of the mask 212 is trimmed using a plasma comprising hydrogen bromide (HBr) at a flow rate of 3 to 200 sccm, oxygen at a flow rate of 5 to 100 sccm (corresponds to a HBr:O₂ flow ratio ranging from 1:30 to 40:1), carbon tetrafluoride (CF₄), and argon (Ar) at a flow rate of 10 to 200 sccm. The plasma is generated using a plasma power of 200 to about 600 W and a bias power of 15 to 45 W, a wafer pedestal temperature between 0 to 80° C. and a chamber pressure of about 2 to 30 mTorr. The trimming photoresist step 112 is performed for about 20 to about 180 seconds.

One photoresist trimming process is performed using HBr at a flow rate of 80 sccm, O₂ at a flow rate of 28 sccm (i.e., a HBr:O₂ flow ratio of about 2.5:1), Ar at a flow rate of 20 sccm, a plasma power of 500 W, a bias power of 0 W, and a wafer pedestal temperature of 65 degrees Celsius at a chamber pressure of 4 mTorr.

Etching hardmask and gate electrode layer step 116 is illustrated by FIG. 2J. At step 116, the pattern of the photoresist is transferred through the hard mask layer 208 and gate electrode layer 206. During step 116 the mask layer 208 is etched using a fluorocarbon gas (e.g., carbon tetrafluoride (CF₄), sulfur hexafluoride (SF₆), trifluoromethane (CHF₃), and difluoromethane (CH₂F₂)). Thereafter, the gate electrode layer 206 is etched using an etch process that includes a gas (or gas mixture) comprising hydrogen bromide (HBr), oxygen (O₂), and at least one inert gas, such as, for example, argon (Ar), helium (He), and neon (Ne). The terms “gas” and “gas mixture” are used interchangeably. In one embodiment, step 116 uses the photoresist mask 212 as an etch mask and the gate electrode layer 206 as an etch stop layer. Alternatively, an endpoint detection system of the etch reactor may monitor plasma emissions at a particular wavelength to determine an end of the etch process. Further, both etch processes of step 116 may be performed in-situ (i.e., in the same etch reactor).

In one illustrative embodiment, the hardmask layer 208 comprising silicon oxynitride (SiON) is etched using carbon tetrafluoride (CF₄) at a flow rate of 40 to 200 sccm, argon (Ar) at a flow rate of 40 to 200 sccm (i.e., a CF₄:Ar flow ratio of 1:5 to 5:1), plasma power of 250 W to 750 W, bias power of 0 to 300 W, and maintaining the wafer pedestal at a temperature between 40 and 85° C. at a chamber pressure of 2 to 10 mTorr. The hardmask layer 208 etch process is terminated by observing the magnitude of the plasma emission spectrum at 3865 Angstroms, which will drop significantly after the underlying gate electrode layer 206 is reached, and subsequently conducting a 40 percent over etch (i.e., continuing the etch process for 40 percent of the time that led up to the observed change in the magnitude of the emission spectra).

One exemplary silicon oxynitride (SiON) hardmask layer 208 etch process is performed using carbon tetrafluoride (CF₄) at a flow rate of 120 sccm, argon (Ar) at a flow rate of 120 sccm (i.e., a CF₄:Ar flow ratio of about 1:1), a plasma power of 360 W, a bias power of 60 W, a wafer pedestal temperature of about 65° C., and a chamber pressure of 4 mTorr.

In one illustrative embodiment, the gate electrode layer 206 is etched using hydrogen bromide (HBr) at a flow rate of 20 to 100 sccm, oxygen (O₂) at a flow rate of 5 to 60 sccm (i.e., a HBr:O₂ flow ratio of 1:3 to 20:1) argon (Ar) at a flow rate of 20 to 100 sccm, plasma power of 500 W to 1500 W, bias power of 0 to 300 W, and maintaining the wafer pedestal at a temperature between 40 and 85 degrees Celsius at a chamber pressure of 2 to 10 mTorr. The gate electrode layer 206 etch process is terminated by observing the magnitude of the plasma emission spectrum at 4835 Angstroms, and subsequently conducting a 30% over etch to remove residues (i.e., continuing the etch process for 30% of the time that led up to the observed change in the magnitude of the emission spectra).

One exemplary gate electrode layer 206 etch process is performed using hydrogen bromide (HBr) at a flow rate of 60 sccm, oxygen (O₂) at a flow rate of 20 sccm (i.e., a HBr:O₂ flow ratio of about 3:1), Ar at a flow rate of 60 sccm, a plasma power of 600 W, a bias power of 100 W, a wafer pedestal temperature of 65 degrees Celsius, and a pressure of 4 mTorr. Such process has etch directionality of at least 20:1. Herein the term “etch directionality” is used to describe a ratio of the etch rates at which the gate electrode layer 206 is removed on horizontal surfaces and on vertical surfaces, such as sidewalls 261. During step 110, the high etch directionality of the etch process protects the sidewalls 261 of the photoresist mask 212 and gate electrode layer 206 from lateral etching and, as such, preserves the dimensions thereof.

Also at step 116, the photoresist 212 is removed (or stripped) from the substrate (FIG. 2J). Generally, step 116 is performed using a conventional photoresist stripping process that uses an oxygen-based chemistry, e.g., a gas mixture comprising oxygen and nitrogen. During step 116, the etching chemistry and process parameters are specifically selected to provide high etch directionality to preserve the dimensions and location of the gate electrode layer 206. In one illustrative embodiment, step 116 is performed in-situ using the DPS II module.

One exemplary photoresist stripping process is performed using hydrogen bromide (HBr) at a flow rate of 60 sccm, oxygen (O₂) at a flow rate of 20 sccm (i.e., a HBr:O₂ flow ratio of about 3:1), argon (Ar) at a flow rate of 60 sccm, a plasma power of 600 W, a bias power of 100 W, a wafer pedestal temperature of 65 degrees Celsius, and a chamber pressure of 4 mTorr. The process has etch directionality of at least 10:1, as well as etch selectivity to the DARC film 208 (e.g., silicon oxynitride (SiON)) over photoresist (mask 212) of at least 1:20.

### EXAMPLE

In one exemplary process, bottom antireflective coating (BARC) is etched with 20 sccm HBr, 60 sccm CF₄, and 45 sccm oxygen at 4 mTorr with a plasma power of 400 W and bias of 60 W. The etch time at 19 W DC is 35 seconds. The trim step is performed with the same properties as the BARC etch, except the bias is 30 W and the time is 20 seconds. In a following hardmask etch step, a mixture of gases including 30 sccm SF₆, 35 sccm CH₂F₂, 45 sccm N₂, and 200 sccm He is introduced into a chamber at 4 mTorr with a plasma power of 450 W and bias of 60 W at 11 W DC.

A soft landing is performed with 300 sccm HBr and 6.5 sccm O₂ at a pressure of 6 mTorr. The plasma power is 400 W and the bias is 30 W with a DC of 11 W. An overetch step is performed with 300 sccm HBr, 20 sccm HeO₂, and 200 sccm He at 70 mTorr. The plasma power for the overetch is 300 W, the bias is 30 W, and the DC is 19 W.

The invention may be practiced using other semiconductor wafer processing systems wherein the processing parameters may be adjusted to achieve acceptable characteristics by those skilled in the arts by utilizing the teachings disclosed herein without departing from the spirit of the invention.

Although the forgoing discussion referred to fabrication of the field effect transistor, fabrication of the other devices and structures used in the integrated circuits can benefit from the invention.

While the foregoing is directed to embodiments of the present invention, other and further embodiments of the invention may be devised without departing from the basic scope thereof, and the scope thereof is determined by the claims that follow.

1. A method of reducing line edge roughness, comprising:
patterning a photoresist to form lines in the photoresist that define lines in an underlying layer;
depositing a post development material between the lines in the photoresist;
curing and removing the post development material to reduce line edge roughness;
trimming the lines in the photoresist; and then
etching the underlying layer.

2. The method of claim 1, wherein the post development material is a shrink resist.

3. The method of claim 1, wherein the underlying layer is a mask adjacent a gate electrode.

4. The method of claim 2, wherein the shrink resist comprises poly (methyladamantyltrifluoromethacrylate(MAFMA)-norbornenehexafluoroisopropanol (NBHFA)).

5. The method of claim 2, wherein the shrink resist is cured at a temperature of about 120 to about 150° C.

6. The method of claim 5, wherein the shrink resist is cured for about 20 to about 180 seconds.

7. The method of claim 1, wherein the trimming the lines in the photoresist occurs at a temperature of about 0 to about 80° C.

8. The method of claim 7, wherein the trimming the lines in the photoresist occurs for about 20 to about 180 seconds.

9. The method of claim 1, wherein removing the post development material occurs at a temperature of about 0 to about 65° C. and atmospheric pressure.

10. (canceled)

11. A method of reducing line edge roughness, comprising:
patterning a photoresist to define lines in the photoresist for etching an underlying layer, wherein the underlying layer is a gate electrode;
depositing a shrink resist between the lines;
curing and removing the shrink resist to reduce line edge roughness;
trimming the lines in the photoresist; and then
etching the underlying layer.

12. The method of claim 11, wherein the shrink resist comprises poly (methyladamantyltrifluoromethacrylate(MAFMA)-norbornenehexafluoroisopropanol(NBHFA)).

13. The method of claim 11, wherein the shrink resist is cured at a temperature of about 120 to about 150° C.

14. The method of claim 13, wherein the shrink resist is cured for about 20 to about 180 seconds.

15. The method of claim 11, wherein the trimming the lines in the photoresist occurs at a temperature of 0 to 80° C.

16. The method of claim 15, wherein the trimming the lines in the photoresist occurs for about 20 to about 180 seconds.

17. The method of claim 11, wherein removing the shrink resist occurs at a temperature of 0 to 65° C.

18. The method of claim 17, wherein the removing the shrink resist occurs for about 20 to about 180 seconds.
